(19) United States
(12) Patent Application Publication
(10) Pub. No.: US 2026/0213517 A1
(43) Pub. Date: Jul. 23, 2026

(54) ISOLATION INTEGRATED CIRCUIT AND COMMON MODE TRANSIENT DETECTION CIRCUIT THEREOF

(71) Applicant: PowerX Semiconductor Corporation, Hsinchu County (TW)

(72) Inventor: Chih-Yuan HSU, Hsinchu County (TW)

(21) Appl. No.: 19/254,018

(22) Filed: Jun. 30, 2025

(30) Foreign Application Priority Data
Jan. 20, 2025 (TW) 114102378

(51) Int. Cl. H02H 1/00; H03K 3/037

(52) U.S. Cl. CPC H02H 1/0007; H03K 3/0375

(57) ABSTRACT

The present disclosure provides an isolation integrated circuit including a receiver circuit and a common mode transient (CMT) detection circuit. The receiver circuit generates an output voltage according to an input voltage at its input node. The CMT detection circuit includes a current generation circuit, a bias circuit, a warning circuit and a control circuit. The bias circuit is coupled to the input node and the current generation circuit, and enables the current generation circuit in response to a change in the input voltage due to a CMT event, to generate detection current. The warning circuit is coupled to the bias circuit, and generates a warning signal according to the detection current. The control circuit is coupled to the warning circuit, and selectively masks the output voltage according to the warning signal, to generate a receiver output signal at an output node of the receiver circuit.

### RELATED APPLICATIONS

This application claims priority to Taiwan Application Serial Number 114102378, filed Jan. 20, 2025, which is herein incorporated by reference.

### BACKGROUND

### Field of Disclosure

The present disclosure relates to a common mode transient (CMT) detection circuit, and particularly relates to a CMT detection circuit applicable to an isolation integrated circuit.

### Description of Related Art

In the related fields of an isolation gate driver, some events, such as common mode transient (CMT) events often occur. The CMT event causes some voltage surges generated at the at least one input node. These voltage surges result in some currents generated in the isolation gate driver thereby causing damage to the isolation gate driver, or affect the operation of the isolation gate driver thereby causing the erroneous output of the isolation gate driver. Therefore, it is necessary to improve the isolation gate driver to address the above problems.

### SUMMARY

An embodiment of the present disclosure is a common mode transient (CMT) detection circuit. The CMT detection circuit is applicable to a receiver circuit of an isolation integrated circuit, and includes a first current generation circuit, a first bias circuit, a first warning circuit and a control circuit. The first current generation circuit is configured to receive a reference voltage, and is configured to generate one of a first transient current and a second transient current in response to a level change in a first input voltage at a first input node of the receiver circuit due to a CMT event. The first bias circuit is coupled to the first input node and the first current generation circuit, is configured to receive the first input voltage, and is configured to enable the first current generation circuit in response to the level change in the first input voltage, to generate one of a first detection current and a second detection current according to the one of the first transient current and the second transient current. The first warning circuit is coupled to the first bias circuit at a first node and a second node, is configured to receive the one of the first detection current and the second detection current, and is configured to generate a first warning signal according to the one of the first detection current and the second detection current. The control circuit is coupled to the first warning circuit and a first output node of the receiver circuit, is configured to receive the first warning signal and a first output voltage which is generated by the receiver circuit according to the first input voltage, and is configured to selectively mask the first output voltage according to a voltage level of the first warning signal, to generate a first receiver output signal at the first output node.

An embodiment of the present disclosure is an isolation integrated circuit. The isolation integrated circuit includes a receiver circuit, a signal processing circuit and a common mode transient (CMT) detection circuit. The signal processing circuit is coupled to a first input node of the receiver circuit, and is configured to generate a first output voltage according to a first input voltage at the first input node. The CMT detection circuit is coupled to the first input node, the signal processing circuit and a first output node of the receiver circuit, is configured to detect a CMT event according to the first input voltage, and is configured to mask the first output voltage when the CMT event occurs, to generate a first receiver output signal at the first output node. The CMT detection circuit includes a first current generation circuit, a first bias circuit, a first warning circuit and a control circuit. The first current generation circuit is configured to receive a reference voltage, and is configured to generate one of a first transient current and a second transient current in response to a level change in the first input voltage due to the CMT event. The first bias circuit is coupled to the first input node and the first current generation circuit, configured to receive the first input voltage, and is configured to enable the first current generation circuit in response to the level change in the first input voltage, to generate one of a first detection current and a second detection current according to the one of the first transient current and the second transient current. The first warning circuit is coupled to the first bias circuit at a first node and a second node, is configured to receive the one of the first detection current and the second detection current, and is configured to generate a first warning signal according to the one of the first detection current and the second detection current. The control circuit is coupled to the first warning circuit, the signal processing circuit and the first output node, is configured to receive the first warning signal and the first output voltage, and is configured to selectively mask the first output voltage according to a voltage level of the first warning signal, to generate the first receiver output signal at the first output node.

In sum, by the CMT detection circuit, the isolation integrated circuit of the present disclosure can mask the output voltage which may be affected by the CMT event when the CMT event occurs, to achieve the technical effects of preventing the receiver circuit from outputting the output voltage having the non-ideal voltage level and/or waveform to the subsequent circuit of the isolation integrated circuit. Therefore, the isolation integrated circuit of the present disclosure has the advantages of high reliability.

### BRIEF DESCRIPTION OF THE DRAWINGS

FIG. 1 is a circuit block diagram of an isolation integrated circuit in accordance with some embodiments of the present disclosure;

FIG. 2 is a circuit block diagram of a common mode transient (CMT) detection circuit in accordance with some embodiments of the present disclosure;

FIG. 3A is a circuit schematic diagram of a CMT detection circuit in accordance with some embodiments of the present disclosure;

FIG. 3B is a circuit schematic diagram of a CMT detection circuit in accordance with some embodiments of the present disclosure;

FIG. 4 is a circuit block diagram of another CMT detection circuit in accordance with some embodiments of the present disclosure;

FIG. 5 is a circuit schematic diagram of a control circuit of FIG. 4 in accordance with some embodiments of the present disclosure;

FIG. 6 is a circuit block diagram of yet another CMT detection circuit in accordance with some embodiments of the present disclosure; and

FIG. 7 is a circuit schematic diagram of a control circuit of FIG. 6 in accordance with some embodiments of the present disclosure.

### DETAILED DESCRIPTION

The following is a detailed description of embodiments in conjunction with the drawings. However, the specific embodiments described are only intended to explain the present disclosure, rather than to limit the present disclosure. The description of structural operations is not used to limit the order of execution thereof. Devices with equal effects, structurally formed by the recombination of elements, are all within the scope of the present disclosure.

Terms used throughout the specification and the claims of the present disclosure, unless otherwise specified, generally have the ordinary meaning of each term used in the art, in the present disclosure and in special contents.

The term “coupled” or “coupled” used herein may indicate that two or more elements are in direct physical or electrical contact with each other, or that two or more elements are in indirect physical or electrical contact with each other, and also may indicate that two or more elements co-operate or interact with each other.

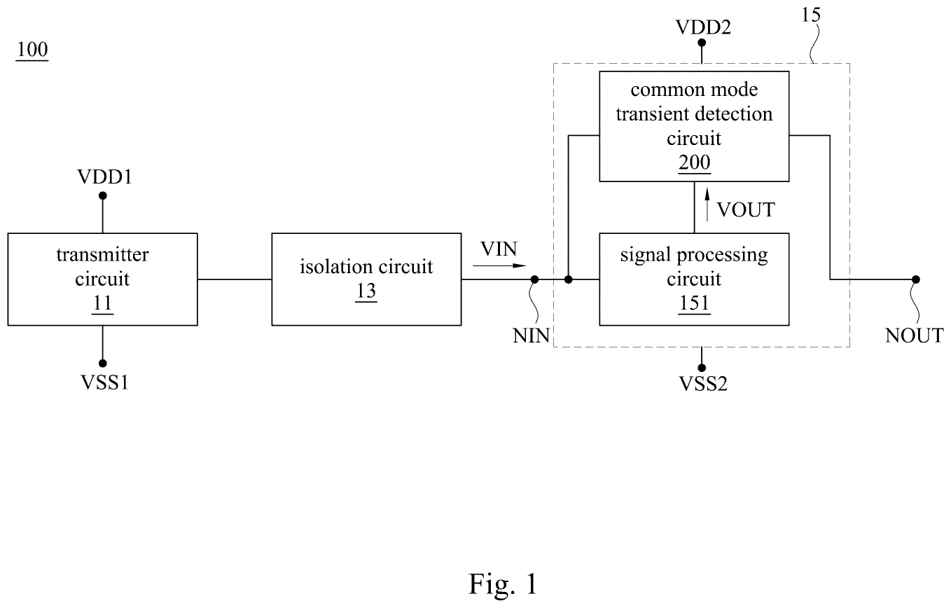

Referring to FIG. 1, FIG. 1 is a circuit block diagram of an isolation integrated circuit 100 in accordance with some embodiments of the present disclosure. As shown in FIG. 1, the isolation integrated circuit 100 includes a transmitter circuit 11, an isolation circuit 13 and a receiver circuit 15. In particular, the isolation integrated circuit 100 can be implemented by an isolation gate driver.

In some embodiments, the isolation circuit 13 is coupled to a signal output terminal (not shown in the drawings) of the transmitter circuit 11 and further to a signal input terminal (not shown in the drawings) of the receiver circuit 15 at an input node NIN. Thus, the isolation circuit 13 operates as an electrical isolation barrier between the transmitter circuit 11 and the receiver circuit 15. In particular, the isolation circuit 13 can be implemented by a capacitor or other insulators (e.g., a transformer).

Due to the configuration of the isolation circuit 13, the transmitter circuit 11 and the receiver circuit 15 can be operated in two different voltage domains, respectively. For example, as shown in FIG. 1, the transmitter circuit 11 can be biased by a power voltage VDD1 and a ground voltage VSS1, and the receiver circuit 15 can be biased by a power voltage VDD2 and a ground voltage VSS2. It should be understood that the power voltage VDD1 and the power voltage VDD2 can be different from each other. Also, the ground voltage VSS1 and the ground voltage VSS2 can be different from each other.

In some embodiments, the transmitter circuit 11 can be implemented by various circuits, such as logic circuit(s), oscillator(s), modulator(s), transmitter(s), etc., to convert an input signal (not shown in the drawings) received by the isolation integrated circuit 100 into a modulated signal (not shown in the drawings). While being used as the electrical isolation barrier between the transmitter circuit 11 and the receiver circuit 15, the isolation circuit 13 is further configured to convert the modulated signal outputted by the transmitter circuit 11 by, for example, voltage coupling, to generate an input voltage VIN at the input node NIN. Therefore, the receiver circuit 15 can receive the input voltage VIN through the input node NIN.

In addition, as shown in FIG. 1, the receiver circuit 15 includes a signal processing circuit 151. The signal processing circuit 151 of the receiver circuit 15 can be implemented by various circuits, such as logic circuit(s), demodulator(s), receiver(s), etc. In such arrangements, the receiver circuit 15 can demodulate the input voltage VIN by the signal processing circuit 151 to generate an output voltage VOUT. From these descriptions, it can be seen that the signal processing circuit 151 generates the output voltage VOUT according to the input voltage VIN.

In some embodiments, a common mode transient (CMT) event may occur in the isolation integrated circuit 100. When the CMT event occurs, a voltage level of the input voltage VIN at the input node NIN may be steeply increased or decreased. In some practical applications, a drastic change in the input voltage VIN due to the CMT event can affect the generation of the output voltage VOUT by the signal processing circuit 151, which results in the output voltage VOUT having a non-ideal voltage level and/or waveform. Therefore, the isolation integrated circuit 100 of FIG. 1 uses a CMT detection circuit 200 for responding to these situations.

In some embodiments, the CMT detection circuit 200 is arranged in the receiver circuit 15 of the isolation integrated circuit 100. As shown in FIG. 1, the CMT detection circuit 200 is coupled to the input node NIN, the signal processing circuit 151 and an output node NOUT of the receiver circuit 15. The CMT detection circuit 200 is configured to detect the CMT event according to the input voltage VIN and further to mask the output voltage VOUT when the CMT event occurs. For example, the CMT detection circuit 200 can maintain a voltage level of the output voltage VOUT in a state which the voltage level of the output voltage VOUT was in before the occurrence of the CMT event. In another example, the CMT detection circuit 200 can replace the output voltage VOUT during the occurrence of the CMT event by a blank signal (not shown in the drawings) as an output of the receiver circuit 15. In such way, the receiver circuit 15 can be prevented from transmitting the output voltage VOUT, which has the non-ideal voltage level and/or waveform due to the CMT event, to a subsequent circuit (not shown in the drawings) of the isolation integrated circuit 100. It should be understood that the output node NOUT of the receiver circuit 15 can be regarded as a signal output terminal of the isolation integrated circuit 100 for coupling to the subsequent circuit.

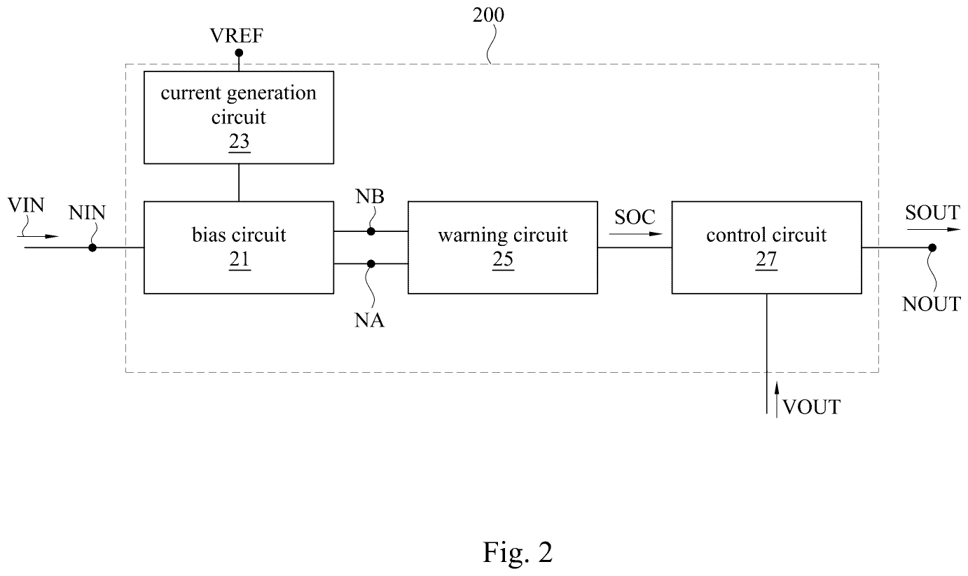

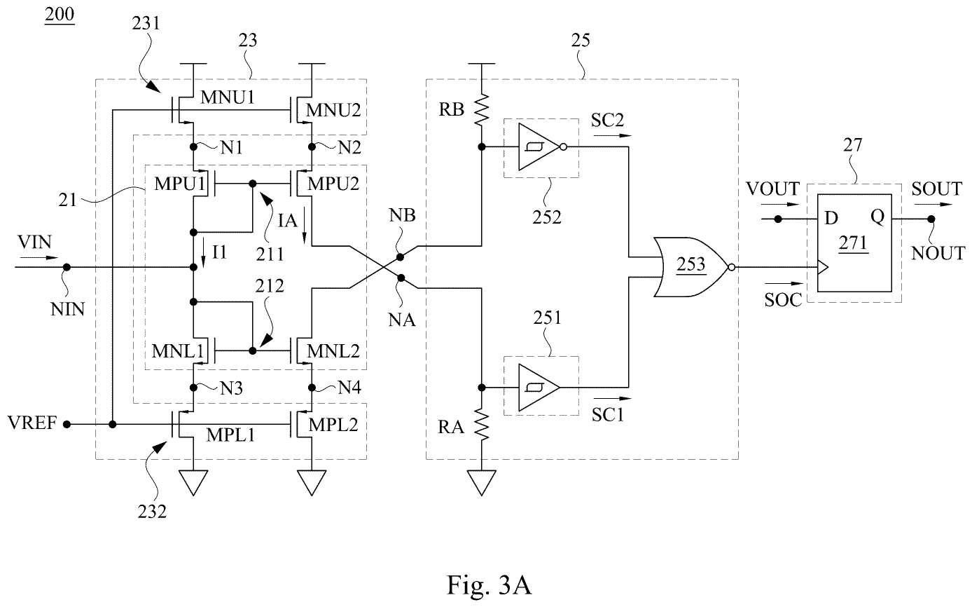

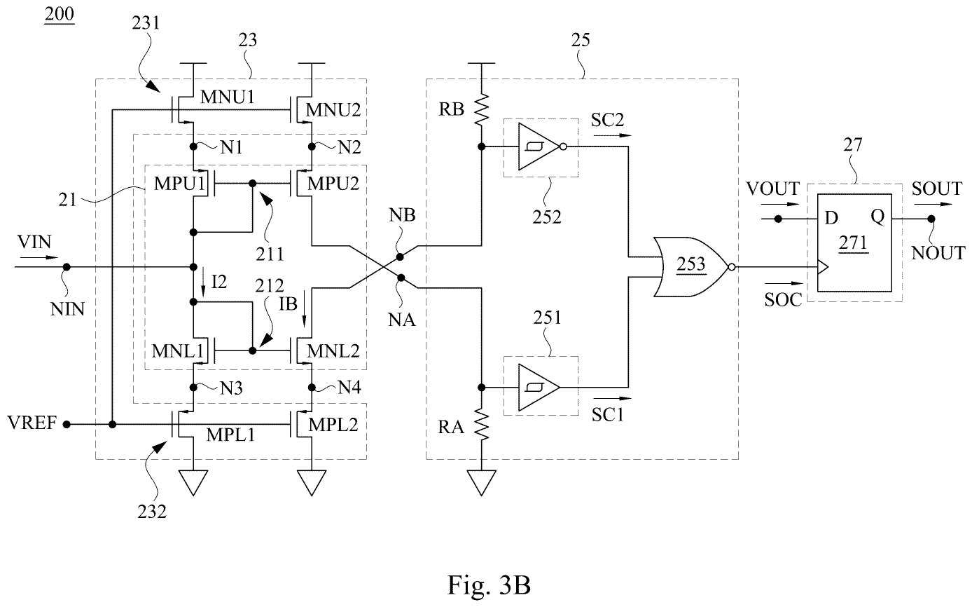

The CMT detection circuit 200 would be described in detail with reference to FIGS. 2 and 3A-3B. FIG. 2 is a circuit block diagram of the CMT detection circuit 200 in accordance with some embodiments of the present disclosure. In some embodiments, the CMT detection circuit 200 includes a bias circuit 21, a current generation circuit 23, a warning circuit 25 and a control circuit 27. The bias circuit 21 is coupled to the input node NIN of the receiver circuit 15. The current generation circuit 23 is coupled to the bias circuit 21 and configured to receive a reference voltage VREF. The warning circuit 25 is coupled to the bias circuit 21, for example, at nodes NA and NB. The control circuit 27 is coupled to the warning circuit 25 and the output node NOUT and further to the signal processing circuit 151 to receive the output voltage VOUT.

FIGS. 3A and 3B are circuit schematic diagrams of the CMT detection circuit 200 during the CMT event in accordance with some embodiments of the present disclosure. In some embodiments, the bias circuit 21 includes current mirror circuits 211 and 212. The current mirror circuit 211 is composed of transistors MPU1 and MPU2. A first terminal (e.g., a source terminal) of the transistor MPU1 is coupled to the current generation circuit 23 at a node N1, and a second terminal (e.g., a drain terminal) thereof is coupled to the input node NIN and a control terminal (e.g., a gate terminal) of the transistor MPU1. A first terminal of the transistor MPU2 is coupled to the current generation circuit 23 at a node N2, a second terminal thereof is coupled to the warning circuit 25 at the node NA, and a control terminal thereof is coupled to the control terminal of the transistor MPU1, the second terminal of the transistor MPU1 and the input node NIN. From these descriptions, it can be seen that the current mirror circuit 211 is coupled to the input node NIN, coupled to the current generation circuit 23 at the nodes N1 and N2, and further coupled to the warning circuit 25 at the node NA.

In accordance with the above descriptions, the current mirror circuit 212 is composed of transistors MNL1 and MNL2. A first terminal of the transistor MNL1 is coupled to the current generation circuit 23 at a node N3, and a second terminal thereof is coupled to the input node NIN and a control terminal of the transistor MNL1. A first terminal of the transistor MNL2 is coupled to the current generation circuit 23 at a node N4, a second terminal thereof is coupled to the warning circuit 25 at the node NB, and a control terminal thereof is coupled to the control terminal of the transistor MNL1, the second terminal of the transistor MNL1 and the input node NIN. From these descriptions, it can be seen that the current mirror circuit 212 is coupled to the input node NIN, coupled to the current generation circuit 23 at the nodes N3 and N4, and further coupled to the warning circuit 25 at the node NB.

In the above embodiments, each of the transistors MPU1 and MPU2 of the bias circuit 21 can be implemented by a P-type metal oxide semiconductor transistor, and each of the transistors MNL1 and MNL2 of the bias circuit 21 can be implemented by a N-type metal oxide semiconductor transistor. However, the present disclosure is not limited herein.

In some embodiments, the current generation circuit 23 includes a transistor pair 231 and another transistor pair 232. The transistor pair 231 includes transistors MNU1 and MNU2. A first terminal of the transistor MNU1 is coupled to the node N1, a second terminal thereof is coupled to a power voltage (e.g., the power voltage VDD2 of FIG. 1), and a control terminal thereof is coupled to the reference voltage VREF. A first terminal of the transistor MNU2 is coupled to the node N2, a second terminal thereof is coupled to the power voltage, and a control terminal thereof is coupled to the reference voltage VREF. From these descriptions, it can be seen that the transistor pair 231 is coupled between the reference voltage VREF and the current mirror circuit 211, in which the transistor pair 231 is coupled to the current mirror circuit 211 at the nodes N1 and N2.

In accordance with the above descriptions, the transistor pair 232 includes transistors MPL1 and MPL2. A first terminal of the transistor MPL1 is coupled to the node N3, a second terminal thereof is coupled to a ground voltage (e.g., the ground voltage VSS2 of FIG. 1), and a control terminal thereof is coupled to the reference voltage VREF. A first terminal of the transistor MPL2 is coupled to the node N4, a second terminal thereof is coupled to the ground voltage, and a control terminal thereof is coupled to the reference voltage VREF. From these descriptions, it can be seen that the transistor pair 232 is coupled between the reference voltage VREF and the current mirror circuit 212, in which the transistor pair 232 is coupled to the current mirror circuit 212 at the nodes N3 and N4.

In the above embodiments, each of the transistors MNU1 and MNU2 of the current generation circuit 23 can be implemented by a N-type metal oxide semiconductor transistor, and each of the transistors MPL1 and MPL2 of the current generation circuit 23 can be implemented by a P-type metal oxide semiconductor transistor. However, the present disclosure is not limited herein.

In some embodiments, the warning circuit 25 includes resistors RA and RB, comparison circuits 251 and 252 and a logic gate 253. The resistor RA is coupled to the node NA and the ground voltage, and the resistor RB is coupled to the node NB and the power voltage. An input terminal of the comparison circuit 251 is coupled to the node NA, and an output terminal thereof is coupled to a first input terminal of the logic gate 253. An input terminal of the comparison circuit 252 is coupled to the node NB, and an output terminal thereof is coupled to a second input terminal of the logic gate 253. An output terminal of the logic gate 253 is coupled to the control circuit 27.

In the above embodiment, the comparison circuit 251 can be implemented by a non-inverting Schmitt trigger, the comparison circuit 252 can be implemented by an inverting Schmitt trigger, and the logic gate 253 can be implemented by an NOR gate. However, the present disclosure is not limited herein.

In some embodiments, the control circuit 27 includes a latch circuit 271. A data input terminal D of the latch circuit 271 is coupled to the signal processing circuit 151 to receive the output voltage VOUT. A gate control terminal (presented by a symbol “>” in FIGS. 3A and 3B) of the latch circuit 271 is coupled to the output terminal of the logic gate 253. A data output terminal Q of the latch circuit 271 is coupled to the output node NOUT. In particular, the latch circuit 271 can be implemented by circuit(s), such as a SR latch circuit, a gated D latch circuit, etc.

In the embodiments of FIG. 3A, it is assumed that the voltage level of the input voltage VIN at the input node NIN is steeply decreased due to the CMT event. In this case, the transistors MPU1 and MPU2 are switched to a turned-on state, and the transistors MNL1 and MNL2 are maintained in a turned-off state. Also, the node N1 is biased by the transistor MPU1 according to the voltage level of the input voltage VIN and a gate-source voltage of the transistor MPU1, so that the transistor MNU1 is switched to the turned-on state. Meanwhile, the node N2 is biased by the transistor MPU2 according to the voltage level of the input voltage VIN and a gate-source voltage of the transistor MPU2, so that the transistor MNU2 is switched to the turned-on state. Based on the transistors MPU1 and MNU1 being turned on, the transistor MNU1 generates a transient current I1 which flows sequentially through the transistor MNU1, the node N1, the transistor MPU1 and the input node NIN. In other words, the transistor pair 231 is biased by the current mirror circuit 211, so that the transient current I1 is generated. Then, the current mirror circuit 211 copies the transient current I1 to generate a detection current IA which flows sequentially through the transistor MNU2, the node N2, the transistor MPU2 and the node NA.

In accordance with the above descriptions, the detection current IA flows to the resistor RA from the node NA, so that an input terminal voltage (not shown in the drawings) of the comparison circuit 251 is increased. When the input terminal voltage of the comparison circuit 251 is increased to be greater than an upper voltage threshold (not shown in the drawings) of the comparison circuit 251, the comparison circuit 251 outputs a comparison signal SC1 with an enable level (e.g., logic “1”). The logic gate 253 performs a NOR operation according to the comparison signal SC1 with the enable level to output a warning signal SOC with a disable level (e.g., logic “0”). Then, since the warning signal SOC with the disable level is inputted to the gate control terminal of the latch circuit 271, the latch circuit 271 maintains a voltage at the data output terminal Q. For example, if the latch circuit 271 outputs the output voltage VOUT with the enable level as the receiver output signal SOUT at the last moment before the CMT event occurs, the receiver output signal SOUT outputted by the latch circuit 271 when the CMT event occurs is still at the enable level (even if the output voltage VOUT is switched to the disable level at this time). It should be understood that the input terminal voltage of the comparison circuit 251 can also be regarded as a voltage at the node NA.

In the embodiments of FIG. 3B, it is assumed that the voltage level of the input voltage VIN at the input node NIN is steeply increased due to the CMT event. In this case, the transistors MNL1 and MNL2 are switched to the turned-on state, and the transistors MPU1 and MPU2 are maintained in the turned-off state. Also, the node N3 is biased by the transistor MNL1 according to the voltage level of the input voltage VIN and a gate-source voltage of the transistor MNL1, so that the transistor MPL1 is switched to the turned-on state. Meanwhile, the node N4 is biased by the transistor MNL2 according to the voltage level of the input voltage VIN and a gate-source voltage of the transistor MNL2, so that the transistor MPL2 is switched to the turned-on state. Based on the transistors MNL1 and MPL1 being turned on, the transistor MPL1 generates a transient current I2 which flows sequentially through the input node NIN, the transistor MNL1, the node N3 and the transistor MPL1. In other words, the transistor pair 232 is biased by the current mirror circuit 212, so that the transient current I2 is generated. Then, the current mirror circuit 212 copies the transient current I2 to generate a detection current IB which flows sequentially through the node NB, the transistor MNL2, the node N4 and the transistor MPL2.

In accordance with the above descriptions, the detection current IB flows out of the resistor RB and to the node NB, so that an input terminal voltage (not shown in the drawings) of the comparison circuit 252 is decreased. When the input terminal voltage of the comparison circuit 252 is decreased to be smaller than a lower voltage threshold (not shown in the drawings) of the comparison circuit 252, the comparison circuit 252 outputs a comparison signal SC1 with the enable level. The logic gate 253 performs the NOR operation according to the comparison signal SC2 with the enable level to output the warning signal SOC with the disable level. Then, since the warning signal SOC with the disable level is inputted to the gate control terminal of the latch circuit 271, the latch circuit 271 maintains the voltage at the data output terminal Q, which is similar to the descriptions of the latch circuit 271 in the embodiments of FIG. 3A. It should be understood that the input terminal voltage of the comparison circuit 252 can also be regarded as a voltage at the node NB.

In some embodiments, there is no CMT event in the isolation integrated circuit 100. The CMT detection circuit 200 of FIGS. 3A and 3B ensures that the transistors MNU1, MNU2, MPL1 and MPL2 are all in the turned-off state by the configurations of the reference voltage VREF and the bias circuit 21, that is, the current generation circuit 23 is disabled, which further ensures that the bias circuit 21 does not output the detection current IA and the detection current IB. Therefore, the input terminal voltage of the comparison circuit 251 (which is equivalent to the ground voltage VSS2) is smaller than a lower voltage threshold (not shown in the drawings) of the comparison circuit 251, so that the comparison circuit 251 outputs the comparison signal SC1 with the disabled level. It should be understood that the upper voltage threshold of the comparison circuit 251 is greater than the lower voltage threshold of the comparison circuit 251. Also, the input terminal voltage of the comparison circuit 252 (which is equivalent to the power supply voltage VDD2) is greater than an upper voltage threshold (not shown in the drawings) of the comparison circuit 252, so that the comparison circuit 252 outputs the comparison signal SC2 with the disabled level. It should be understood that the upper voltage threshold of the comparison circuit 252 is greater than the lower voltage threshold of the comparison circuit 252. Then, the logic gate 253 performs the NOR operation according to both the comparison signal SC1 with the disable level and the comparison signal SC2 with the disable level to output the warning signal SOC with the enable level.

In accordance with the above descriptions, since the warning signal SOC with the enable level is inputted to the gate control terminal of the latch circuit 271, the latch circuit 271 directly outputs the output voltage VOUT generated by the signal processing circuit 151 from the data output terminal Q. In other words, when no CMT event occurs in the isolation integrated circuit 100, the control circuit 27 performs no process (e.g., masking) on the output voltage VOUT, and directly transmits the output voltage VOUT to the output node NOUT as the output of the receiver circuit 15, that is, as the receiver output signal SOUT. In brief, when no CMT event occurs in the isolation integrated circuit 100, the CMT detection circuit 200 does not change or affect the normal operations of the receiver circuit 15 (i.e., the operations of the signal processing circuit 151) in the isolation integrated circuit 100.

From the descriptions of the above embodiments, it can be seen that, in some embodiments, the bias circuit 21 is configured to enable the current generation circuit 23 (that is, the bias circuit 21 is configured to switch the transistors MNU1 and MNU2 (or the transistors MPL1 and MPL2) to the turned-on state) in response to the level change in the input voltage VIN due to the CMT event, so that the transient current I1 (or the transient current I2) is generated. The current generation circuit 23 is configured to generate the transient current I1 (or the transient current I2) in response to the level change in the input voltage VIN due to the CMT event, so that the bias circuit 21 generates the detection current IA (or the detection current IB). The warning circuit 25 is configured to generate the warning signal SOC according to the detection current IA (or the detection current IB). The control circuit 27 is configured to selectively mask the output voltage VOUT according to the voltage level (i.e., the disable level or the enable level) of the warning signal SOC to generate the receiver output signal SOUT at the output node NOUT.

Furthermore, when the warning signal SOC is at the enable level (which means there is no CMT event in the isolation integrated circuit 100), a voltage level of the receiver output signal SOUT may be equal to a voltage level of the output voltage VOUT in real time. When the warning signal SOC is at the disable level (which means the CMT event occurs in the isolation integrated circuit 100), the voltage level of the receiver output signal SOUT may not be equal to the voltage level of the output voltage VOUT in real time.

In the above embodiments, as shown in FIGS. 3A and 3B, the warning circuit 25 performs a current-to-voltage conversion on the detection current IA (or the detection current IB) by the resistor RA (or the resistor RB) to generate the warning signal SOC. It should be understood that the warning circuit 25 of the present disclosure is not limit to the circuit architectures as shown in the embodiments of FIGS. 3A and 3B. For example, in some embodiments, he resistors RA and RB are omitted, and each of the comparison circuits 251 and 252 in the warning circuit 25 can be implemented by a current comparator. In such arrangements, the warning circuit 25 can compare the detection current IA with a current threshold (not shown in the drawings) by the comparison circuit 251 to generate the comparison signal SC1, and can further compare the detection current IB with another current threshold (not shown in the drawings) by the comparison circuit 252 to generate the comparison signal SC2. Also, the warning circuit 25 can output the warning signal SOC according to the comparison signal SC1 and the comparison signal SC2 by the logic gate 253.

Moreover, in the above embodiment, as shown in FIG. 1, the receiver circuit 15 has a single-ended input architecture. Also, the CMT detection circuit 200 in FIG. 2 is applicable to the receiver circuit 15 having the single-ended input architecture. It should be understood that the receiver circuit in the isolation integrated circuit 100 of the present disclosure is not limited to the single-ended input architecture as shown in the embodiments of FIGS. 1 and 2.

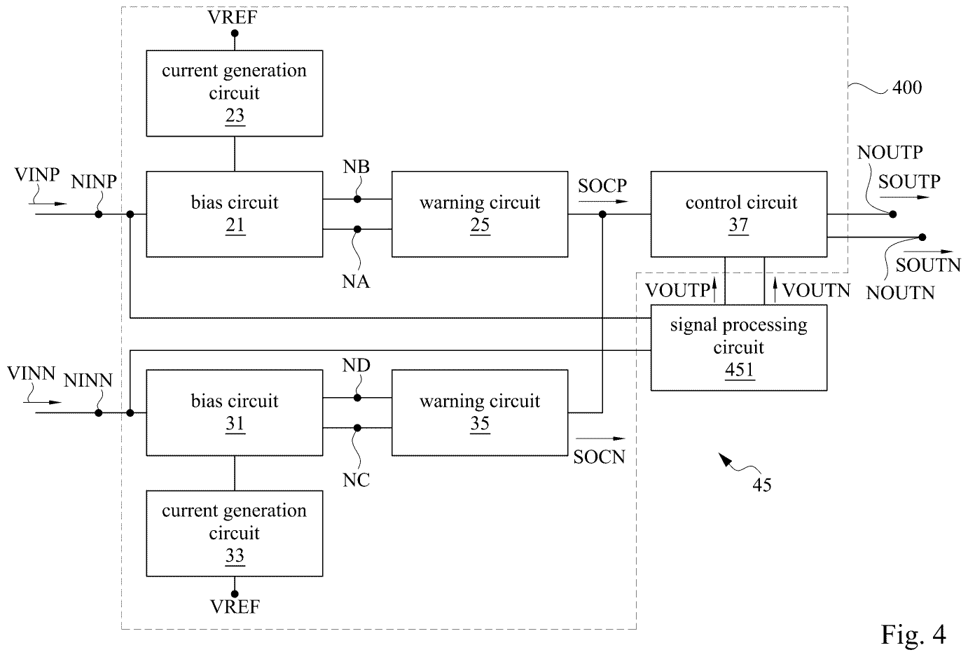

Referring to FIG. 4, FIG. 4 is a circuit block diagram of a CMT detection circuit 400 applicable to a receiver circuit 45 having a differential input architecture in accordance with some embodiments of the present disclosure. In some embodiments, a signal processing circuit 451 of the receiver circuit 45 is coupled to an input node NINP and another input node NINN, and generates output voltages VOUTP and VOUTN according to an input voltage VINP at the input node NINP and another input voltage VINN at the input node NINN, in which the input voltages VINP and VINN form a differential input signal, and the output voltages VOUTP and VOUTN form a differential output signal. In particular, the signal processing circuit 451 of the receiver circuit 45 can be implemented by various circuits, such as logic circuit(s), demodulator(s), receiver(s), etc.

In the embodiments of FIG. 4, the CMT detection circuit 400 is coupled to the input node NINP, the input node NINN, the signal processing circuit 451 and output nodes NOUTP and NOUTN of the receiver circuit 45. As shown in FIGS. 2 and 4, in comparison with the circuit configuration of the CMT detection circuit 200 in FIG. 2, the CMT detection circuit 400 in FIG. 4 further includes another bias circuit 31, another current generation circuit 33 and another warning circuit 35. In addition, a control circuit 37 of the CMT detection circuit 400 is slightly different from the control circuit 27 of the CMT detection circuit 200.

The bias circuit 21 is coupled to the input node NINP. The current generation circuit 23 is coupled to the bias circuit 21, and receives the reference voltage VREF. The warning circuit 25 is coupled to the bias circuit 21 at the nodes NA and NB. The bias circuit 31 is coupled to the input node NINN. The current generation circuit 33 is coupled to the bias circuit 31, and receives the reference voltage VREF. The warning circuit 35 is coupled to the bias circuit 31 at nodes NC and ND. In addition, the control circuit 37 is coupled to the warning circuit 25, the warning circuit 35 and the output nodes NOUTP and NOUTN, and receives the output voltages VOUTP and VOUTN generated by the signal processing circuit 451.

The circuit architectures of the bias circuits 21 and 31 in FIG. 4 can be similar to that of the bias circuit 21 in FIGS. 3A and 3B. The circuit architectures of the current generation circuits 23 and 33 in FIG. 4 can be similar to that of the current generation circuit 23 in FIGS. 3A and 3B. In addition, the circuit architectures of the warning circuits 25 and 35 in FIG. 4 can be similar to that of the warning circuit 25 in FIGS. 3A and 3B. The operations of the bias circuits 21 and 31, the current generation circuits 23 and 33, and the warning circuits 25 and 35 in FIG. 4 can be referred to the relevant descriptions in FIGS. 3A and 3B.

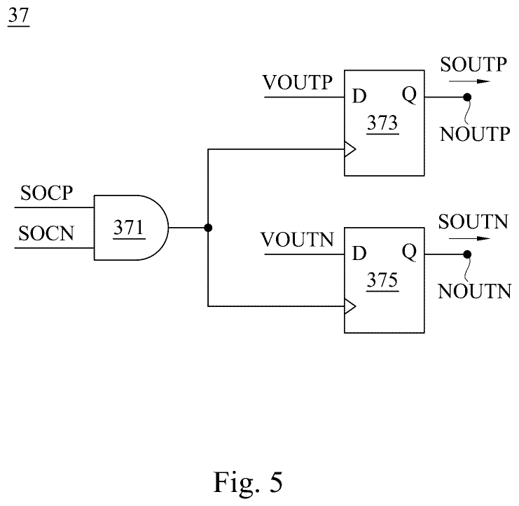

In accordance with the above descriptions, referring to FIG. 5, the control circuit 37 includes an AND gate 371 and latch circuits 373 and 375. Two input terminals of the AND gate 371 are coupled to the output terminal of the warning circuit 25 and the output terminal of the warning circuit 35, respectively, and an output terminal of the AND gate 371 can be coupled to the gate control terminals of the latch circuits 373 and 375. The data input terminal D of the latch circuit 373 receives the output voltage VOUTP generated by the signal processing circuit 451, and the data output terminal Q of the latch circuit 373 is coupled to the output node NOUTP. The data input terminal D of the latch circuit 375 receives the output voltage VOUTN generated by the signal processing circuit 451, and the data output terminal Q of the latch circuit 375 is coupled to the output node NOUTN.

Similar to the descriptions of the embodiments of FIGS. 2, 3A and 3B, the bias circuit 21 enables the current generation circuit 23 in response to the level change in the input voltage VINP due to the CMT event, to generate the detection current IA flowing to the node NA (or the detection current IB flowing out of the node NB) according to the transient current I1 (or the transient current I2) generated by the current generation circuit 23. The warning circuit 25 generates a warning signal SOCP according to the detection current IA flowing to the node NA (or the detection current IB flowing out of the node NB). The bias circuit 31 enables the current generation circuit 33 in response to the level change in the input voltage VINN due to the CMT event, to generate a detection current flowing to the node NC (or another detection current flowing out of the node ND) according to a transient current from the current generation circuit 33 to the bias circuit 31 (or another transient current from the bias circuit 31 to the current generation circuit 33). The warning circuit 35 generates another warning signal SOCN according to the detection current flowing to the node NC (or the detection current flowing out of the node ND).

By the circuit configuration of the control circuit 37, when at least one of the input voltage VINP and the input voltage VINN changes drastically due to the CMT event, the AND gate 371 can perform an AND operation according to at least one of the warning signal SOCP with the disable level and the warning signal SOCN with the disable level to output a logic signal (not shown) with the disable level to the gate control terminals of the latch circuits 373 and 375. Accordingly, the latch circuits 373 and 375 of the control circuit 37 maintain the voltages at the data output terminals Q, that is, maintain the voltage levels of the receiver output signals SOUTP and SOUTN generated at the output nodes NOUTP and NOUTN, respectively.

Moreover, when the CMT event does not occur, the warning circuit 25 outputs the warning signal SOCP with the enable level, and the warning circuit 35 outputs the warning signal SOCN with the enable level. The AND gate 371 can perform the AND operation according to the warning signal SOCP with the enable level and the warning signal SOCN with the enable level to output the logic signal with the enable level to the gate control terminals of the latch circuits 373 and 375. Accordingly, the latch circuits 373 and 375 of the control circuit 37 directly output the output voltages VOUTP and VOUTN generated by the signal processing circuit 451 from the data output terminals Q, respectively, as the receiver output signals SOUTP and SOUTN.

From the above descriptions, it can be seen that the control circuit 37 is configured to selectively mask the output voltages VOUTP and VOUTN according to the voltage level of the warning signal SOCP and the voltage level of the warning signal SOCN, to generate the receiver output signals SOUTP and SOUTN at the output nodes NOUTP and NOUTN respectively. Furthermore, when the warning signals SOCP and SOCN are both at the enabled levels (which means the CMT event does not occur), the voltage levels of the receiver output signals SOUTP and SOUTN may be equal to the voltage levels of the output voltages VOUTP and VOUTN in real time. When at least one of the warning signals SOCP and SOCN is at the disable level (which means the CMT event occurs), the voltage levels of the receiver output signals SOUTP and SOUTN may not be equal to the voltage levels of the output voltages VOUTP and VOUTN in real time.

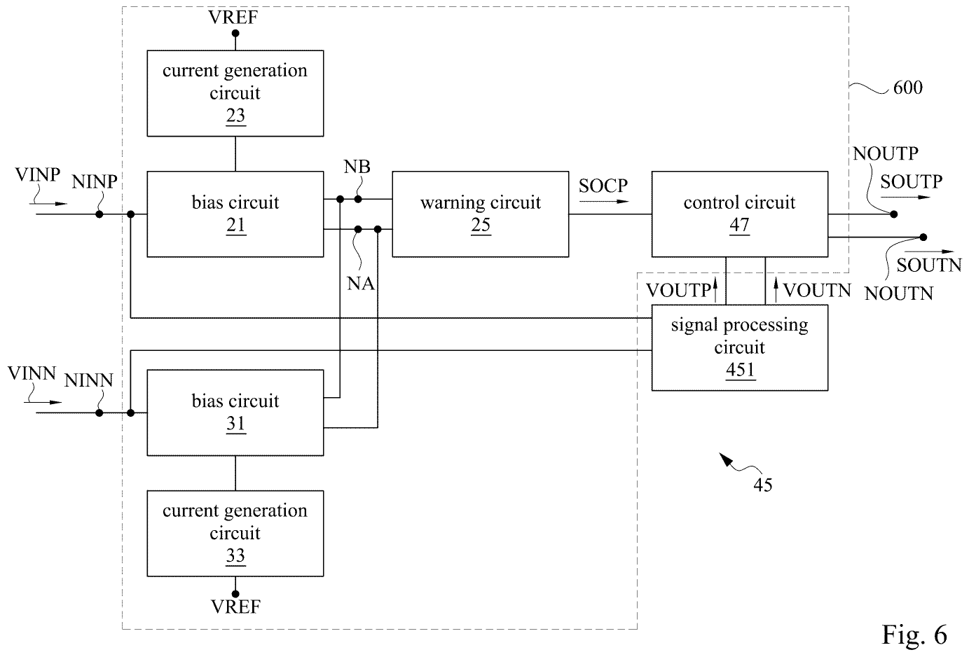

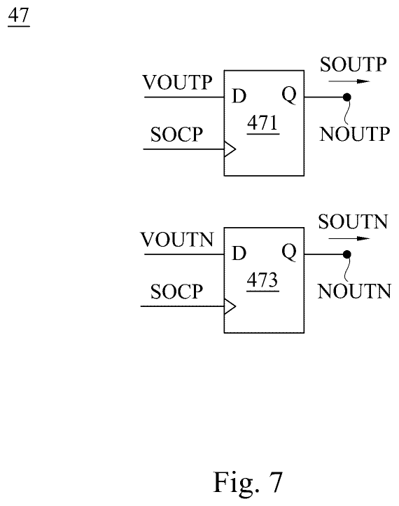

It should be understood that the CMT detection circuit 400 applicable to the receiver circuit 45 having the differential input architecture is not limited to the circuit configuration as shown in the embodiments of FIG. 4. For example, referring to FIG. 6, in some embodiments, a CMT detection circuit 600 is applicable to the receiver circuit 45 having the differential input architecture. The CMT detection circuit 600 of FIG. 6 includes the bias circuits 21 and 31, the current generation circuits 23 and 33, the alarm circuit 25 and a control circuit 47, that is, the alarm circuit 35 in FIG. 4 can be omitted, and the bias circuit 31 can be coupled to the alarm circuit 25 at the nodes NA and NB. Referring to FIG. 7, the control circuit 47 includes latch circuits 471 and 473. The gate control terminals of the latch circuits 471 and 473 are both coupled to the output terminal of the warning circuit 25. The data input terminal D of the latch circuit 471 receives the output voltage VOUTP generated by the signal processing circuit 451, and the data output terminal Q thereof is coupled to the output node NOUTP. The data input terminal D of the latch circuit 473 receives the output voltage VOUTN generated by the signal processing circuit 451, and the data output terminal Q thereof is coupled to the output node NOUTN. By such arrangements, when at least one of the bias circuits 21 and 31 generates at least one detection current (e.g., the detection current IA, the detection current IB, a detection current generated by the bias circuit 31 and flowing to the node NA from the bias circuit 31, another detection current generated by the bias circuit 31 and flowing to the bias circuit 31 from the node NB, etc.) due to the CMT event, the warning circuit 25 can generate the warning signal SOCP according to the at least one detection current. The control circuit 47 receives the warning signal SOCP, and can selectively mask the output voltages VOUTP and VOUTN according to the voltage level of the warning signal SOCP, to generate the receiver output signals SOUTP and SOUTN at the output nodes NOUTP and NOUTN.

In accordance with the above embodiments of the present disclosure, by the CMT detection circuit 200 (or the CMT detection circuit 400, the CMT detection circuit 600, etc.), the isolation integrated circuit 100 of the present disclosure can mask the output voltage VOUT (or the output voltages VOUTP and VOUTN) which may be affected by the CMT event when the CMT event occurs, to achieve the technical effects of preventing the receiver circuit 15 (or the receiver circuit 45) from outputting the output voltage VOUT having the non-ideal voltage level and/or waveform to the subsequent circuit of the isolation integrated circuit 100. Therefore, the isolation integrated circuit 100 of the present disclosure has the advantages of high reliability.

Although the present disclosure has been disclosed as above by way of the embodiments, these embodiments are not intended to limit the present disclosure. Those skilled in the art may make various changes and modifications without departing from the spirit and scope of the present disclosure. Therefore, the scope of protection of the present disclosure is to be determined as defined by the appended claims.

What is claimed is:

1. A common mode transient (CMT) detection circuit, applicable to a receiver circuit of an isolation integrated circuit, and comprising:
a first current generation circuit, configured to receive a reference voltage, and configured to generate one of a first transient current and a second transient current in response to a level change in a first input voltage at a first input node of the receiver circuit due to a CMT event;
a first bias circuit, coupled to the first input node and the first current generation circuit, configured to receive the first input voltage, and configured to enable the first current generation circuit in response to the level change in the first input voltage, to generate one of a first detection current and a second detection current according to the one of the first transient current and the second transient current;
a first warning circuit, coupled to the first bias circuit at a first node and a second node, configured to receive the one of the first detection current and the second detection current, and configured to generate a first warning signal according to the one of the first detection current and the second detection current; and
a control circuit, coupled to the first warning circuit and a first output node of the receiver circuit, configured to receive the first warning signal and a first output voltage which is generated by the receiver circuit according to the first input voltage, and configured to selectively mask the first output voltage according to a voltage level of the first warning signal, to generate a first receiver output signal at the first output node.

2. The CMT detection circuit according to claim 1, wherein the first bias circuit comprises:
a first current mirror circuit, coupled to the first input node, coupled to the first current generation circuit at a third node and a fourth node, coupled to the first warning circuit at the first node, and configured to copy the first transient current to generate the first detection current flowing sequentially through the fourth node and the first node, wherein the first transient current flows sequentially through the third node and the first input node; and
a second current mirror circuit, coupled to the first input node, coupled to the first current generation circuit at a fifth node and a sixth node, coupled to the first warning circuit at the second node, and configured to copy the second transient current to generate the second detection current flowing sequentially through the second node and the sixth node, wherein the second transient current flows sequentially through the first input node and the fifth node.

3. The CMT detection circuit according to claim 2, wherein when the first current generation circuit comprises:
a first transistor pair, coupled to the reference voltage, coupled between a power voltage and the first current mirror circuit, coupled to the first current mirror circuit at the third node and the fourth node, and configured to be biased by the first current mirror circuit, so that the first transient current is generated; and
a second transistor pair, coupled to the reference voltage, coupled between a ground voltage and the second current mirror circuit, coupled to the second current mirror circuit at the fifth node and the sixth node, and configured to be biased by the second current mirror circuit, so that the second transient current is generated;
wherein one of the first transistor pair and the second transistor pair is biased by a corresponding one of the first current mirror circuit and the second current mirror circuit in response to the level change in the first input voltage.

4. The CMT detection circuit according to claim 2, wherein the first warning circuit comprises:
a first comparison circuit, coupled to the first current mirror circuit at the first node, and configured to compare the first detection current with a first current threshold, to generate a first comparison signal;
a second comparison circuit, coupled to the second current mirror circuit at the second node, and configured to compare the second detection current with a second current threshold, to generate a second comparison signal; and
a logic gate, coupled to the first comparison circuit and the second comparison circuit, and configured to output the first warning signal according to the first comparison signal and the second comparison signal, wherein the first warning signal is at a disable level when at least one of the first comparison signal and the second comparison signal is at an enable level, and wherein the control circuit masks the first output voltage according to the first warning signal with the disable level, so that a voltage level of the first receiver output signal is not equal to a voltage level of the first output voltage in real time.

5. The CMT detection circuit according to claim 2, wherein the first warning circuit comprises:
a first resistor, coupled to the first current mirror circuit at the first node;
a second resistor, coupled to the second current mirror circuit at the second node;
a first comparison circuit, coupled to the first current mirror circuit at the first node, and configured to compare a voltage at the first node with a first voltage threshold, to generate a first comparison signal;
a second comparison circuit, coupled to the second current mirror circuit at the second node, and configured to compare a voltage at the second node with a second voltage threshold, to generate a second comparison signal; and
a logic gate, coupled to the first comparison circuit and the second comparison circuit, and configured to output the first warning signal according to the first comparison signal and the second comparison signal, wherein the first warning signal is at a disable level when at least one of the first comparison signal and the second comparison signal is at an enable level, and wherein the control circuit masks the first output voltage according to the first warning signal with the disable level, so that a voltage level of the first receiver output signal is not equal to a voltage level of the first output voltage in real time.

6. The CMT detection circuit according to claim 1, wherein the control circuit comprises:
a latch circuit, wherein a gate control terminal of the latch circuit is coupled to the first warning circuit to receive the first warning signal, a data input terminal of the latch circuit receives the first output voltage, and a data output terminal of the latch circuit is coupled to the first output node to output the first receiver output signal.

7. The CMT detection circuit according to claim 6, wherein when the first warning signal with a disable level is inputted to the gate control terminal of the latch circuit, the latch circuit maintains a voltage at the data output terminal, so that a voltage level of the first receiver output signal is not equal to a voltage level of the first output voltage in real time.

8. The CMT detection circuit according to claim 6, wherein when the first warning signal with an enable level is inputted to the gate control terminal of the latch circuit, the latch circuit directly outputs the first output voltage from the data output terminal, so that a voltage level of the first receiver output signal is equal to a voltage level of the first output voltage in real time.

9. The CMT detection circuit according to claim 1, further comprising:
a second current generation circuit, configured to receive the reference voltage, and configured to generate one of a third transient current and a fourth transient current in response to a level change in a second input voltage at a second input node of the receiver circuit due to the CMT event; and
a second bias circuit, coupled to the second input node and the second current generation circuit, configured to receive the second input voltage, and configured to enable the second current generation circuit in response to the level change in the second input voltage, to generate one of a third detection current and a fourth detection current.

10. The CMT detection circuit according to claim 9, wherein the second bias circuit is coupled to the first warning circuit at the first node and the second node;
wherein the first warning circuit is configured to generate the first warning signal according to at least one of the first detection current, the second detection current, the third detection current and the fourth detection current, the first detection current flows to the first node from the first bias circuit, the second detection current flows to the first bias circuit from the second node, the third detection current flows to the first node from the second bias circuit, and the fourth detection current flows to the second bias circuit from the second node.

11. The CMT detection circuit according to claim 9, further comprising:
a second warning circuit, coupled to the second bias circuit at a third node and a fourth node, configured to receive the one of the third detection current and the fourth detection current, and configured to generate a second warning signal according to the one of the third detection current and the fourth detection current;
wherein the control circuit is coupled to the second warning circuit and a second output node of the receiver circuit, configured to receive the second warning signal and a second output voltage which is generated by the receiver circuit according to the second input voltage, and configured to selectively mask the first output voltage and the second output voltage according to the voltage level of the first warning signal and a voltage level of the second warning signal, to generate the first receiver output signal and a second receiver output signal at the first output node and the second output node, respectively.

12. The CMT detection circuit according to claim 11, wherein the control circuit comprises:
a logic gate, coupled to the first warning circuit and the second warning circuit, and configured to output a logic signal according to the voltage level of the first warning circuit and the voltage level of the second warning circuit;
a first latch circuit, wherein a gate control terminal of the first latch circuit is coupled to an output terminal of the logic gate to receive the logic signal, a data input terminal of the first latch circuit receives the first output voltage, and a data output terminal of the first latch circuit is coupled to the first output node to output the first receiver output signal; and
a second latch circuit, wherein a gate control terminal of the second latch circuit is coupled to the output terminal of the logic gate to receive the logic signal, a data input terminal of the second latch circuit receives the second output voltage, and a data output terminal of the second latch circuit is coupled to the second output node to output the second receiver output signal.

13. The CMT detection circuit according to claim 12, wherein when the logic signal with a disable level is inputted to the gate control terminal of the first latch circuit and the gate control terminal of the second latch circuit, the first latch circuit maintains a voltage at the data output terminal, and the second latch circuit maintains a voltage at the data output terminal, so that the first receiver output signal and the second receiver output signal are not equal to the first output voltage and the second output voltage in real time, respectively.

14. The CMT detection circuit according to claim 12, wherein when the logic signal with an enable level is inputted to the gate control terminal of the first latch circuit and the gate control terminal of the second latch circuit, the first latch circuit directly outputs the first output voltage from the data output terminal, and the second latch circuit directly outputs the second output voltage from the data output terminal, so that the first receiver output signal and the second receiver output signal are equal to the first output voltage and the second output voltage in real time, respectively.

15. An isolation integrated circuit, comprising:
a receiver circuit, comprising:
a signal processing circuit, coupled to a first input node of the receiver circuit, and configured to generate a first output voltage according to a first input voltage at the first input node; and
a common mode transient (CMT) detection circuit, coupled to the first input node, the signal processing circuit and a first output node of the receiver circuit, configured to detect a CMT event according to the first input voltage, and configured to mask the first output voltage when the CMT event occurs, to generate a first receiver output signal at the first output node;
wherein the CMT detection circuit comprises:
a first current generation circuit, configured to receive a reference voltage, and configured to generate one of a first transient current and a second transient current in response to a level change in the first input voltage due to the CMT event;
a first bias circuit, coupled to the first input node and the first current generation circuit, configured to receive the first input voltage, and configured to enable the first current generation circuit in response to the level change in the first input voltage, to generate one of a first detection current and a second detection current according to the one of the first transient current and the second transient current;
a first warning circuit, coupled to the first bias circuit at a first node and a second node, configured to receive the one of the first detection current and the second detection current, and configured to generate a first warning signal according to the one of the first detection current and the second detection current; and
a control circuit, coupled to the first warning circuit, the signal processing circuit and the first output node, configured to receive the first warning signal and the first output voltage, and configured to selectively mask the first output voltage according to a voltage level of the first warning signal, to generate the first receiver output signal at the first output node.

16. The isolation integrated circuit according to claim 15, wherein the first bias circuit comprises:
a first current mirror circuit, coupled to the first input node, coupled to the first current generation circuit at a third node and a fourth node, coupled to the first warning circuit at the first node, and configured to copy the first transient current to generate the first detection current flowing sequentially through the fourth node and the first node, wherein the first transient current flows sequentially through the third node and the first input node; and
a second current mirror circuit, coupled to the first input node, coupled to the first current generation circuit at a fifth node and a sixth node, coupled to the first warning circuit at the second node, and configured to copy the second transient current to generate the second detection current flowing sequentially through the second node and the sixth node, wherein the second transient current flows sequentially through the first input node and the fifth node.

17. The isolation integrated circuit according to claim 16, wherein the first current generation circuit comprises:
a first transistor pair, coupled to the reference voltage, coupled between a power voltage and the first current mirror circuit, coupled to the first current mirror circuit at the third node and the fourth node, and configured to be biased by the first current mirror circuit, so that the first transient current is generated; and
a second transistor pair, coupled to the reference voltage, coupled between a ground voltage and the second current mirror circuit, coupled to the second current mirror circuit at the fifth node and the sixth node, and configured to be biased by the second current mirror circuit, so that the second transient current is generated;
wherein one of the first transistor pair and the second transistor pair is biased by one of the first current mirror circuit and the second current mirror circuit in response to the level change in the first input voltage.

18. The isolation integrated circuit according to claim 16, wherein the first warning circuit comprises:
a first resistor, coupled to the first current mirror circuit at the first node;
a second resistor, coupled to the second current mirror circuit at the second node;
a first comparison circuit, coupled to the first current mirror circuit at the first node, and configured to compare a voltage at the first node with a first voltage threshold, to generate a first comparison signal;
a second comparison circuit, coupled to the second current mirror circuit at the second node, and configured to compare a voltage at the second node with a second voltage threshold, to generate a second comparison signal; and
a logic gate, coupled to the first comparison circuit and the second comparison circuit, and configured to output the first warning signal according to the first comparison signal and the second comparison signal, wherein the first warning signal is at a disable level when at least one of the first comparison signal and the second comparison signal is at an enable level, and wherein the control circuit masks the first output voltage according to the first warning signal with the disable level, so that a voltage level of the first receiver output signal is not equal to a voltage level of the first output voltage in real time.

19. The isolation integrated circuit according to claim 15, wherein the control circuit comprises:
a latch circuit, wherein a gate control terminal of the latch circuit is coupled to the first warning circuit to receive the first warning signal, a data input terminal of the latch circuit is coupled to the signal processing circuit to receive the first output voltage, and a data output terminal of the latch circuit is coupled to the first output node to output the first receiver output signal.

20. The isolation integrated circuit according to claim 19, wherein when the first warning signal with a disable level is inputted to the gate control terminal of the latch circuit, the latch circuit maintains a voltage at the data output terminal, so that a voltage level of the first receiver output signal is not equal to a voltage level of the first output voltage in real time;
wherein when the first warning signal with an enable level is inputted to the gate control terminal of the latch circuit, the latch circuit directly outputs the first output voltage from the data output terminal, so that the voltage level of the first receiver output signal is equal to the voltage level of the first output voltage in real time.
